(19) United States
(12) Patent Application Publication
(10) Pub. No.: US 2010/0304527 A1
(43) Pub. Date: Dec. 2, 2010

(54) METHODS OF THERMAL PROCESSING A SOLAR CELL

(76) Inventors: Peter BORDEN, San Mateo, CA (US); Sunhom (Steve) Paak, Saratoga, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/717,083

(22) Filed: Mar. 3, 2010

Related U.S. Application Data
(60) Provisional application No. 61/157,179, filed on Mar. 3, 2009.

(51) Int. Cl. H01L 31/18; H05H 1/24

(52) U.S. Cl. 438/87; 427/576; 257/E31.032

(57) ABSTRACT

Embodiments of the invention contemplate the formation of high efficiency solar cells and novel methods for forming the same. Embodiment of the invention can be used to form a solar cell that has doped regions that act as a back surface field. The methods and apparatus disclosed herein may include the use of a doping source, a rapid annealer and a slow annealer. One embodiment of the methods used to form an improved emitter structure include disposing an amount of a dopant atom in a substrate and performing two or more thermal processing steps to cause the dopant to diffuse deeper into the substrate to achieve a desirable multi-facet doping profile.

### CROSS-REFERENCE TO RELATED APPLICATIONS

This application claims the benefit of U.S. Provisional Patent Application Ser. No. 61/157,179, filed Mar. 3, 2009 (Attorney Docket No. APPM/014258L), which is herein incorporated by reference in its entirety.

### BACKGROUND OF THE INVENTION

1. Field of the Invention

Embodiments of the present invention generally relate to solar/photovoltaic cells and the method of forming an emitter structure for the same.

2. Description of the Related Art

Solar or photovoltaic cells are material junction devices which convert sunlight into direct current (DC) electrical power. When exposed to sunlight (consisting of energy from photons), the electric field of solar cell p-n junction separates pairs of free electrons and holes, thus generating a photo-voltage. A circuit from p-side to n-side allows the flow of electrons when the solar cell is connected to an electrical load, while the area and other parameters of the Solar cell junction device determine the available current.

Currently, solar cells and panels are manufactured by starting with many small silicon sheets or substrates as material units and processing them into individual solar cells before they are assembled into modules and panels. These silicon sheets are generally saw-cut p-type boron doped silicon sheets, precut to the sizes and dimensions that will be used. The cutting (sawing) or ribbon formation operation on the silicon sheets damages the surfaces of the precut silicon sheets to some degree, and etching processes are performed on both surfaces of the silicon sheets to remove a thin layer of material from each surface and provide textures thereon.

P-N junctions, a critical component of emitters, are then formed by diffusing or implanting an n-type dopant into the precut p-type silicon substrate. Phosphorus is widely used as the n-type dopant for silicon in solar cells. One example of phosphorus diffusion process includes coating phosphosilicate glass compounds onto the surface of the silicon sheets and performing diffusion/annealing inside a furnace. Another example includes bubbling nitrogen gas through liquid phosphorus oxychloride (POCl₃) sources which are injected into an enclosed quartz furnace loaded with batch-type quartz boats containing the silicon sheets.

Following emitter formation, one or both surfaces of the solar cell can also be coated with suitable dielectrics. Dielectric layers are used to minimize surface charge carrier recombination and some dielectric materials, such as silicon oxide, titanium oxide, or silicon nitride, can be provided as antireflective coating to reduce reflection losses of photons.

The front or sun facing side of the solar cell is then covered with an area-minimized metallic contact grid for transporting current and minimizing current losses due to resistance through silicon-containing layers. Some blockage of sunlight or photons by the contact grid is unavoidable but can be minimized. The bottom of the solar cell is generally covered with a back metal which provides contact for good conduction as well as high reflectivity. Metal grids with patterns of conductive metal lines are used to collect current. Generally, screen printing thick-film technology is used in the solar cell industry to layer a conductive paste of metal materials into a desired pattern and deposit a metal material layer to the surface of the silicon sheets or substrates for forming metal contact fingers or wiring channels on the front and/or back side of the solar cell. Other thin film technologies may be used for contact formation or electrode processing. The deposited metal layer, formed into contacts, is often dried and then fired or sintered at high temperature to form into good conductors in direct contact with underlying silicon materials, and a single solar cell is made. Generally, both silver and aluminum are contained in the screen printing paste for forming back side contacts with good conductor contact to silicon material and easy soldering.

Manufacturing high efficiency solar cells at low cost (providing low unit cost per Watt) is the key to making solar cells more competitive in the generation of electricity for mass consumption. Even small improvements in cost per Watt substantially increase the size of the available market. Therefore, there exists a need for a cost effective method of forming emitters to improve the efficiency of a solar cell in generating and maintaining electron-hole pairs from absorbed photons in the emitters and the efficiency of driving the electrons and holes through the external electrical circuit with a load.

### SUMMARY OF THE INVENTION

The present invention generally provides a method of forming a solar cell device, comprising disposing a first amount of a first dopant within a region of a substrate, heating the substrate to a first temperature for a first period of time so that the first dopant diffuses a first depth within the substrate, and heating the substrate to a second temperature for a second period of time so that the first dopant diffuses a second depth within the substrate.

The present invention generally provides a method of forming a solar cell device, comprising disposing a first amount of a first dopant within a region of a substrate, heating the substrate to a first temperature for a first period of time so that the first dopant diffuses a first depth within the substrate, and heating the substrate to a second temperature for a second period of time so that the first dopant diffuses a second depth within the substrate, wherein the second depth is deeper than the first depth.

The present invention also provides a method of forming a solar cell device, comprising disposing a first amount of a first dopant within a region of a substrate, heating the substrate to a first temperature for a first period of time so that the first dopant diffuses a first depth within the substrate, and heating the substrate to a second temperature for a second period of time so that the first dopant diffuses a second depth within the substrate, wherein the second temperature is greater than the first temperature.

The present invention also provides a processing system, comprising a cluster tool comprising a transfer chamber having a first transfer robot disposed therein, two or more implant chambers coupled to the transfer chamber, wherein the two or more implant chambers comprise a plasma source coupled to a processing region and adapted to maintain a plasma therein, a gas distribution plate configured to distribute a gas to the processing region, a substrate support having a biasing electrode and a substrate supporting surface, wherein the substrate supporting surface is configured to support a substrate in the processing region, and an RF bias power generator coupled to the biasing electrode, two or more second process chambers coupled to the transfer chamber and having a heat source configured to heat one or more substrates to a temperature greater than about 950° C., a load lock chamber coupled to the transfer chamber and having a substrate supporting surface configured to receive a substrate from the first transfer robot, and a substrate interface module having a second transfer robot configured to transfer a substrate between the substrate interface module and the one or more regions of the load lock chamber, and a furnace having a heat source configured to heat one or more substrates to a temperature between about 700 and about 950° C.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A illustrates a process sequence used to form a conventional solar cell device.

FIG. 1B illustrates a sample concentration dopant profile formed during the process sequence discussed in conjunction with FIG. 1A.

FIG. 2A illustrates schematic cross-sectional views of a solar cell substrate according to one embodiment of the invention.

FIG. 2B illustrates a close-up cross-sectional view of a region of the substrate shown in FIG. 2A and its associated concentration dopant profile according to one embodiment of the invention.

FIGS. 3A-3C illustrate various process sequences used to form a solar cell according to various embodiments of the invention.

FIG. 4 is a plan view of a processing system according to one embodiment of the invention.

FIG. 5 is a plan view of a processing system according to another embodiment of the invention.

FIG. 6 is a side cross-sectional view of a processing chamber according to one embodiment of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the invention contemplate the formation of high efficiency solar cells and novel methods for forming the same. Embodiment of the invention can be used to form a solar cell that has doped regions that act as a back surface field. The methods and apparatus disclosed herein may include the use of a doping source, a rapid annealer and a slow annealer. One embodiment of the methods used to form an improved emitter structure include disposing an amount of a dopant atom in a substrate and performing two or more thermal processing steps to cause the dopant to diffuse deeper into the substrate to achieve a desirable multi-facet doping profile. Generally, solar cell substrates that may benefit from the invention include substrates containing organic material, single crystal silicon, multi-crystalline silicon, polycrystalline silicon, germanium (Ge), gallium arsenide (GaAs), cadmium telluride (CdTe), cadmium sulfide (CdS), copper indium gallium selenide (CIGS), copper indium selenide (CulnSe₂), and gallium indium phosphide (GalnP₂) that are used to convert sunlight to electrical power.

### Doped Region Formation Processes

Typically, crystalline solar cells consist of a low doped bulk material and a shallow emitter, wherein the emitter is doped with the opposite conductivity type from the low doped bulk. In one example, the low doped bulk material is a p-type substrate and the emitter is an array of n-type doped regions formed in the substrate. Typically, the emitter region is doped with phosphorous when the substrate comprises a p-type dopant.

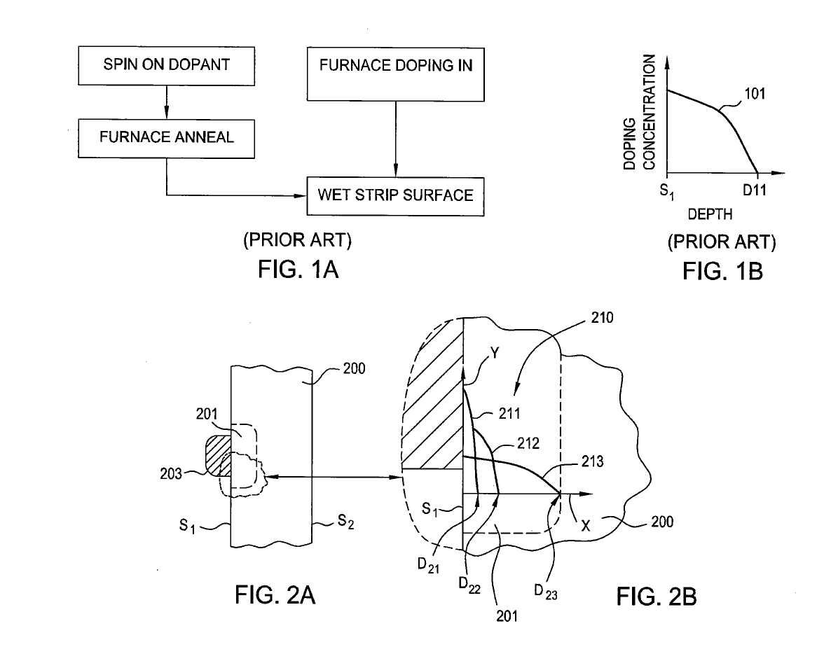

The conventional processes shown in FIG. 1A are commonly used to form the emitter. In one example of a conventional process, a doped glass like material is deposited on the surface of the substrate and the dopant in the deposited material is driven-in using a single furnace anneal processing step. In this variation of the conventional process, the anneal process is typically performed in a belt type furnace. In another example of a conventional process, the doping is done in a tube furnace, using a phosphorus oxychloride (POCl₃) source, which typically causes a p-type doped glass on a surface of the substrate. One will note that, since POCl₃ is a toxic gas, such a process cannot be done in a belt furnace. In either case, the diffusion is carried out at a moderately low anneal temperature, such as between about 875° C. for about 30 minutes to achieve a doping profile 101 similar to what is shown in FIG. 1B. FIG. 1B is a schematic view of a doping profile 101 of a formed emitter region extending from the surface S₁ of the substrate to a depth D₁₁ inside the substrate. In this configuration, the relatively long time required to perform the drive-in process is necessary to take advantage of the fact that phosphorous doping getters defects and contaminants, so sufficient time must be allowed to enable the defects and contaminants to diffuse into the phosphorous containing layer. Typically, these conventional processes lead to significant compromise in the performance of the formed solar cell device. For example, the doping level at the junction must be relatively low, such as about 1×10¹⁸ atoms/cm³ range, to maintain a sufficient emitter lifetime so that the carriers generated in the emitter can be collected. However, such a low doping level in the formed region results in a high contact resistance between the metal contacts and the doped region, which directly affects the efficiency and electrical performance of the formed solar cell device.

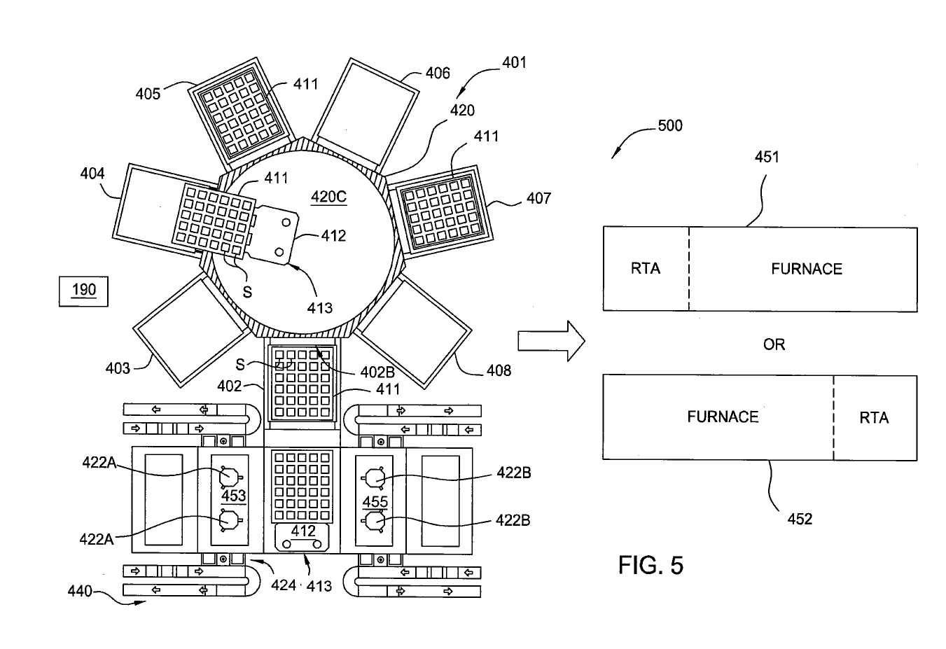

Referring to FIG. 2A-2B, in an effort to resolve the issues typically found in conventional emitter formation processes the following process(es) are used to form a more desirable doping profile. In one embodiment, a process sequence includes the steps of forming the emitter regions using an implantation process, a rapid thermal annealing (RTA) process, and a furnace anneal process, which form a triple layer doping profile that is generally not more complex to produce than the conventional processes described above. FIG. 2B is a schematic representation of the doping profile 210 of an emitter region 201 formed in a substrate 200 using the processing steps described below. The doping profile is a graphical representation of the concentration of the dopant atoms (y-axis) as a function of depth (x-axis) in the substrate as measured, in one embodiment, from a surface “S₁” (e.g., light receiving side of the substrate 200) towards a second surface S₂ (e.g., rear surface of the substrate 200). In one embodiment, the implant process includes a plasma doping process, such as a P3i type process, that is used to form a shallow heavily doped region 211 having a depth D₂₁. In one example, the depth D₂₁ of the shallow heavily doped region 211 is about 100 Å and has a doping concentration of greater than about 1×10²¹ atoms/cm³. It should be noted that a conventional implant process may be used to drive the dopant atoms into the surface of the substrate. In some cases a conventional implant process may have advantages over of a plasma type implant processes, due to the increased doping depth that typical ion-bean type implanters are able to achieve. However, due to the increased capital cost, increased processing costs, and increased defect density created by the more energetic conventional implant processes, some of the benefits of the conventional implanting process can be outweighed by the manufacturability issues that it creates. In one embodiment, an n-type dopant, for example phosphorous (P) or arsenic (As), is implanted into the surface S₁ of a p-type silicon solar cell substrate 200 to form the shallow heavily doped region 211 using a plasma ion immersion implantation (P3i) system available from Applied Materials, Inc., of Santa Clara, Calif. One advantage of using a plasma ion immersion implantation process is the ability to achieve high dosing levels in a short implant time. Unlike most beam-line ion implanters, the substrates sit on an electrical biased horizontal chuck, so many substrates can be implanted in a few seconds. An example of a processing chamber 900 that may be adapted to perform a plasma ion immersion type process is further described below in conjunction with FIG. 5.

In another step of the process sequence, a rapid anneal process, such as a rapid thermal anneal (RTA) process, is used to drive a portion of the shallow doped surface layer into the substrate a depth D₂₂. In one example the depth D₂₂ is about a few hundred angstroms, to create a region 212 in the substrate that has lower doping level, such as about 5×10¹⁹ atoms/cm³ at the depth D₂₂. The formation of the middle region, or region 212, is useful to improve device performance, since it can act as a front surface field that is used to isolate the emitter region from the metal layer 203 formed on the heavily doped region 211, thereby reducing the carrier recombination in the heavily doped region 211.

In another step of the process sequence, furnace anneal process is used to create a still deeper region 213 that has a lower doping concentration. In one example, the region 213 has a doping level of about 1×10¹⁸ atoms/cm³ at a desired depth D₂₃. The processing step used to form the region 213 may be done for a time on the order of about 30 minutes at a temperature of between about 700 and about 950° C. to getter the defects found in the various regions of the substrate, for example, portions of the emitter region 201 that typically contains defects created during the implantation process steps.

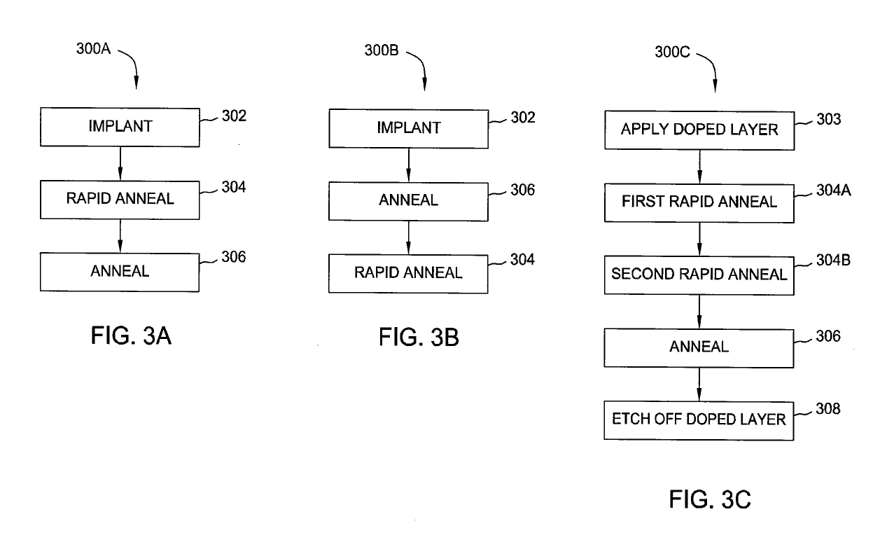

FIGS. 3A-3C illustrate various substrate processing sequences 300A-300C that can be used to form a solar cell device having desirable properties, such as an improved carrier lifetime, lower recombination velocity and higher efficiency. In any of the process sequences disclosed herein it may be desirable to clean one or more of the surfaces of the substrate prior to performing the first processing step in the processing sequence, such as steps 302 or 303, to remove any undesirable material, roughness or contamination. In one embodiment, the solar cell substrate 200 is formed from a crystalline silicon material. In one embodiment, the clean process may be performed using a batch cleaning process in which the substrates are exposed to a cleaning solution. In one embodiment, the substrates are wetted by spraying, flooding, immersing of other suitable technique. The clean solution may be an SC1 cleaning solution, an SC2 cleaning solution, HF-last type cleaning solution, ozonated water solution, hydrofluoric acid (HF) and hydrogen peroxide (H₂O₂) solution, or other suitable and cost effective cleaning solution. The cleaning process may be performed on the substrate between about 5 seconds and about 1800 seconds, such as about 30 seconds to about 240 seconds, for example about 120 seconds. It should be noted that one or more additional processing steps may be added before or after the various steps illustrated in the process sequences 300A-300C, without deviating from the basic scope of the invention described herein. For example, in some solar cell fabrication processing sequences it may be desirable to deposit a doping mask layer prior to performing the implant step to shield various regions of the substrate surface during the implant step. Moreover, it may be desirable to add one or more of the following steps to one of the process sequences, such as: deposit one or more ARC layers or metal layers and/or remove a doping mask layer after performing the implantation step or prior to performing one of the thermal processing steps.

FIG. 3A illustrates one substrate processing sequence 300A, which includes the processing steps 302, 304 and 306. In the first step, or step 302, a desired amount of a dopant material is implanted into one or more regions of the substrate to form a doped region, such as the emitter region 201 (FIG. 2A) in the substrate. In one embodiment, as discussed above, the implant process includes forming a shallow heavily doped region 211 having a depth D₂₁ (FIG. 2B). In one example, the shallow heavily doped region 211 has a depth D₂₁ of about 100 Å and has a doping concentration of greater than about 1×10²¹ atoms/cm³. In one embodiment, a heavily doped region 211 is an n-type doped region that is formed over an area of the surface S₁. In one example, phosphorous is implanted using a P3i chamber in a p-type substrate (e.g., boron doped) at an energy of about 3000 eV, approximately equivalent to a 500 eV beam line implant, to reach a dopant distribution centered at a peak depth of about 40 Å in the heavily doped region 211.

Next, in step 304, as shown in FIG. 3A, a rapid anneal process is performed at a high temperature for a short period of time to cause a portion of the dopant atoms in the heavily doped region 211 to diffuse a few hundred angstroms into the substrate 200. In one embodiment, the temperature of the rapid anneal process is greater than about 900° C. The high temperature anneal process can be used to obtain a heavily doped region 212 that has a doping concentration in a range of between about 1×10¹⁹ atoms/cm³ and about 5×10²⁰ atoms/cm³. In some cases, the process variables in step 302 or step 303 may be adjusted so that a desired doping level is achieved in the region 212 based on the type of solar cell being formed. It is believed that the doping level in region 212 is set by the solid solubility of the dopant atoms in the substrate, such the dopant atoms in a crystalline silicon substrate, at the anneal temperature. In one embodiment, a short high temperature anneal processing time is used because the higher temperature will tend to dissociate the defect complexes, which will degrade the bulk carrier lifetime. In another embodiment, the processing temperature is greater than 950° C. and the processing time is less than about 300 seconds. In one embodiment, the processing temperature is greater than 950° C. and the high temperature anneal processing time is between about 5 and about 30 seconds. The actual required time and temperature may need to be adjusted based on the solar cell design, desired doping depths and processing temperatures. It is believed that some of the degradation of the substrate during the high temperature thermal processing, may be recovered with the long low temperature gettering anneal process, such as some of the processes discussed below in conjunction with step 306. In one embodiment, step 304 may be accomplished using any of a number of heating sources, including lamps, heating elements either above the substrate or in the substrate mount, microwaves, or lasers. In one embodiment, step 304 is performed using a chamber similar to the Vantage RadiancePlus RTP chamber available from Applied Materials, Inc. of Santa Clara, Calif.

Next, in step 306, a lower temperature thermal anneal process is performed on the substrate 200 to form a region 213, which has a lower doping concentration. In some embodiments of the invention, the processes performed in step 306 may be accomplished in a tube furnace or belt furnace. An example of a furnace design that may be adapted for use with one or more of the embodiments described herein is further disclosed in the commonly owned U.S. application Ser. No. 12/273,442, filed on Nov. 11, 2008 [Attorney Dkt No. APPM 13854.C1], which is incorporated herein by reference in its entirety. It should be noted that conventional prior art thermal anneal processes, which are typically performed at a processing temperature of about 875° C., represent a compromise between the need achieve an adequate doping level at a desired depth within a reasonable amount of time to form a desirable contact layer without dissociating defect complexes. In one embodiment of the invention, the processes described herein are better able to obtain a desired doping level deeper in the substrate, since a high doping level contact region already exists near the substrate surface, and thus there is no need to adjust its profile during step 306. The lower doping level created during step 306 increases the carrier lifetime in the emitter and also increases the effectiveness of the front surface field layer by providing a greater doping difference. Therefore, a wider range of processing temperatures are possible in step 306 versus the prior art. In one embodiment, the anneal process in step 306 is performed at about 800° C. for about 30 minutes. In another embodiment, the processing temperature is less than 950° C. and the processing time may be greater than about 5 minutes. In another embodiment, the processing temperature may be between about 700° C. and about 800° C., and the processing time may range from about 5 minutes to over 30 minutes. In another embodiment, the processing temperature may be between about 700° C. and about 950° C., and the processing time may range from about 5 minutes to over 30 minutes.

In an alternate embodiment, as shown in FIG. 3B, the substrate processing sequence 300B includes the processing steps 302, 304 and 306 performed in a different order than the processes shown in FIG. 3A. As illustrated in FIG. 3B, the order of the process steps 304 and 306 have been rearranged so that the process step 306 is performed before step 304. It should be noted that steps 304 and 306 may be performed in either order, although, performing step 304 and then step 306, in some cases may be preferred, since the high temperature anneal will tend to “anneal out” any damage created by the implant process, which could enhance the diffusion rate of the dopant atoms in the substrate lattice during the lower temperature anneal step (e.g., step 306).

In an alternate embodiment, as shown in FIG. 3C, the substrate processing sequence 300C includes the processing steps 303, 304A, 304B, 306 and optionally 308. In the first step of the process sequence 300C, or step 303, a doped layer, such as a glass containing layer (e.g., PSG, BSG) or an amorphous silicon (a-Si) layer, is deposited on the surface S₁ of the substrate 200 by use of a “spin-on” process or by a chemical vapor deposition (CVD) process. In general, the properties of the formed doped layer is created so that the shallow heavily doped region 211 can be formed during a subsequent drive-in anneal step. In one embodiment, the doped layer is formed using a PECVD process to form an amorphous silicon layer that is doped with dopant atoms, such as phosphorous (P). In one example, the doped layer is deposited using a gas mixture containing trimethylborane (TMB), silane (SiH₄) and hydrogen (H₂) at a temperature of about 200° C.

In one embodiment of the substrate processing sequence 300C, a first anneal step 304A is performed on the solar cell substrate so that a sufficient concentration of dopant atoms contained in the doped layer (not shown), can be driven into the surface of the substrate. In one embodiment, the first anneal step 304A is performed by use of a laser anneal, a flash anneal (obtained with flash lamps), or a higher temperature thermal process different than the process performed in step 304 discussed above, such as a spike anneal at a high temperature such as about 1150° C. for at most a few seconds. In some cases, the spike anneal can be performed in an RTA chamber using a spike anneal profile that has a high peak temperature for a very short period of time. In one example, the substrate is heated in a rapid thermal annealing (RTA) chamber in a nitrogen (N₂) rich environment to a temperature between about 1000° C. and about 1150° C. for a time of about 1 seconds to about 120 seconds. In one embodiment, the rapid thermal annealing process performed in step 304A includes processing at a temperature that converts the amorphous silicon (a-Si) layer to crystalline silicon (c-Si).

Next, in step 304B, as shown in FIG. 3C, a second rapid anneal process is performed at a high temperature for a short period of time to cause a portion of the dopant atoms in the formed heavily doped region 211 to diffuse a few hundred angstroms into the substrate 200. In one embodiment, the process step 304B is the same as, or similar to, the processes described above in conjunction with step 304 and thus are not re-recited here again.

Next, in step 306, a lower temperature thermal anneal process is performed on the substrate 200 to form region 213, which has a low doping concentration. As similarly discussed above, steps 304B and 306 in process sequence 300C may be performed in any desirable order, and thus the processing sequence configuration shown in FIG. 3C is not intended to be limiting as to the scope of the invention described herein.

Next, at step 308, an optional doping layer removal process is performed to remove any undesirable material left on the surface of the substrate after performing steps 303-306. In one embodiment, the removal process may be performed using a batch wet cleaning process in which the substrates are exposed to a cleaning solution. In one embodiment, the substrates are wetted by spraying, flooding, immersing of other suitable technique. The clean solution may be an SC1 cleaning solution, an SC2 cleaning solution, HF-last type cleaning solution, ozonated water solution, hydrofluoric acid (HF) and hydrogen peroxide (H₂O₂) solution, or other suitable and cost effective cleaning solution. The cleaning process may be performed on the substrate between about 5 seconds and about 1800 seconds.

In one embodiment of a solar cell formation process, the processing step 306, discussed above in conjunction with FIGS. 3A, 3B and 3C, is performed on the substrate 200 during the contact firing process, which is used to cause a metal layer 203 that is disposed on one or more surfaces of the substrate, to form an Ohmic contact with the doped region 201 (e.g., n-type emitter region). However, in some embodiments of the process sequences 300A-300C, this means that step 306 may be performed many processing step removed from the prior steps, such as steps 302, 303 and/or 304. In some processing configurations the steps 302-304 may be separated from the step 306 by an ARC layer deposition step, one or more ARC layer patterning steps, an optical inspection step and/or a metal layer deposition processing steps, to name just a few possible intervening processing steps. In one embodiment of step 306, the substrate 200 is delivered through a conveyor belt type furnace maintained at a temperature between about 800° C. and about 900° C. in the presence of nitrogen (N₂), oxygen (O₂), hydrogen (H₂), air, or combinations thereof for between about 2 seconds and about 30 minutes. In another embodiment, of step 306, the substrate 200 is delivered through a conveyor belt type furnace maintained at a temperature between about 800° C. and about 900° C. in the presence of nitrogen (N₂), oxygen (O₂), hydrogen (H₂), air, or combinations thereof for between about 2 seconds and about 10 seconds. In one example, the substrate 200 is delivered through a conveyor belt type furnace maintained at a temperature of about 880° C. in the presence of nitrogen (N₂), oxygen (O₂), hydrogen (H₂), air, or combinations thereof for between about 2 seconds and about 10 seconds.

In some embodiments, the metal layer 203 forms part of a top contact structure that is generally configured as widely-spaced thin metal lines, or fingers, that supply current to a bus bar, which are both disposed on the light receiving side of a solar cell substrate. In some applications, it is desirable to screen print the metal layer 203, or fingers, on the surface of the solar cell substrate. An Ohmic contact is a region on a semiconductor device that has been prepared so that the current-voltage (I-V) curve of the device is linear and symmetric, i.e., there is no high resistance interface between the doped silicon region of the semiconductor device and the metal contact. Low-resistance, stable contacts are critical for the performance of the solar cell and reliability of the circuits formed in the solar cell fabrication process. In one embodiment, the metal layer 203 is between about 500 and about 50,000 angstroms (Å) thick, about 10 μm to about 200 μm wide, and contain a metal, such as aluminum (Al), silver (Ag), tin (Sn), cobalt (Co), rhenium (Rh), nickel (Ni), zinc (Zn), lead (Pb), palladium (Pd), molybdenum (Mo) titanium (Ti), tantalum (Ta), vanadium (V), tungsten (W), or chrome (Cr). In one example, the metal layer 203 is formed from a metal paste that contains silver (Ag) or tin (Sn).

In one embodiment, the metal layer 203 is deposited on the substrate in a screen printing module positioned within the Softline™ tool available from Baccini S.p.A., which is owned by Applied Materials, Inc. of Santa Clara, Calif. Therefore, in one embodiment of step 306, the substrate is heated to a desired temperature to causes the metal layer 203 to densify and form a bond to the exposed region of the emitter region 201 formed on the substrate and form the doped region 213 within the substrate. In one embodiment, the substrate is heated to a temperature between about 700° C. and about 900° C. for between about 1 and about 10 minutes so that a good ohmic contact can be formed between the densified metal layer 203 and the surface of the exposed region. In yet another embodiment, the substrate is heated to a temperature between about 800° C. and about 900° C. for between about 1 and about 10 seconds so that a good ohmic contact can be formed between the densified metal layer 203 and the surface of the exposed region. While the discussion above generally discusses the use of a screen printing chamber and system to help describe one or more of the embodiments of the present invention this configuration is not intended to limiting as to the scope of the invention, since other patterned material deposition processes and systems may be used in conjunction with the solar cell processing methods described herein without deviating from the basic scope of the invention described herein.

### Hardware Configuration Information

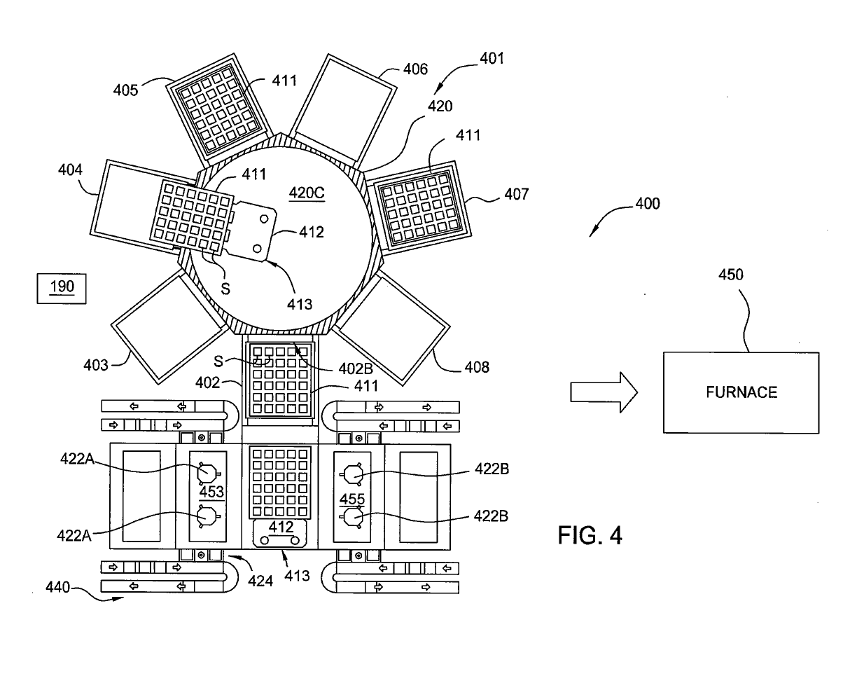

In various embodiment of the invention, one or more of the process sequences discussed above may be performed in a processing system that is configured to perform all of the desired steps in the processing sequence on a substrate. In one embodiment, each of the steps in a desired processing sequence is performed sequentially on a single substrate using one or more single substrate processing chambers contained within a processing system. In another embodiment, in a desired processing sequence is performed on a plurality of substrates at the same time (i.e., processed in a batch) within one or more batch processing chambers contained within a processing system. Examples of a processing system that can be used to perform one or more of the processing steps in one of the process sequences 300A-300C is illustrated in FIGS. 4 and 5. In one embodiment, each of the components in a processing system (e.g., items 401 and 450 in FIG. 4) are interconnected by use of one or more automation systems, such as an automated conveyor system.

FIG. 4 illustrate an embodiment of a substrate processing system 400 that contains a cluster tool 401 and a furnace 450, which are each used to perform one or more of the processing steps in one of the processing sequences 300A-300C. In one embodiment, as shown in FIG. 4, the cluster tool 401 configured to perform one or more solar cell fabrication processes on a planar array, or batch, of substrates according to the present invention. The processing chambers 403-408 contained within the system may include, for example, implant chambers (e.g., P3i chamber) and thermal processing chambers. The cluster tool 401 may also include other processing chambers, such as a physical vapor deposition (PVD), rapid thermal oxidation (RTO) chambers, rapid thermal nitridation (RTN) chambers, plasma enhanced chemical vapor deposition (PECVD) chambers, low pressure chemical vapor deposition (LPCVD) chambers, hot wire chemical vapor deposition (HWCVD) chambers, ion implant/doping chambers, plasma nitridation chambers, atomic layer deposition (ALD) chambers, plasma or vapor chemical etching chambers, substrate reorientation chambers, vapor etching chambers, forming gas or hydrogen annealers, plasma cleaning chambers, and/or other similar processing chambers. It should be noted, that while the discussion below primarily discusses the use of a batch type processing system this configuration is not intended to limiting as to the scope of the invention, since a single substrate processing system may be used without deviating from the basic scope of the invention described herein. One suitable cluster tool that may be adapted to perform one or more of the processes discussed herein may include a processing platform, such as a Gen. 5, Gen. 6, or Gen. 8 processing platform, available from Applied Materials, Inc., located in Santa Clara, Calif.

In one embodiment, the cluster tool 401 typically includes a transfer chamber 420 that is coupled to a substrate transport interface 440 via a load lock chamber 402 that has a slit valve 402B that isolates it from the transfer chamber 420. In certain embodiments, the cluster tool 401 has a single transfer chamber 420 connected to multiple processing chambers and one or more substrate transport interfaces. The transfer chamber 420 generally contains a robot 413 having a blade 412 that is adapted to transfer substrates among a plurality of processing chambers (e.g., reference numerals 403-408) and load lock chambers (e.g., reference numerals 402). Examples of robots that may be adapted for use in the cluster tool 401 are disclosed in commonly owned U.S. application Ser. No. 12/247,135 filed on Oct. 7, 2008 by Kurita et al. and U.S. Pat. No. 6,847,730 issued on Jan. 25, 2005 to Beer et al., both of which are incorporated by reference in their entireties herein to the extent not inconsistent with the present disclosure. In general, the substrate transfer interface 440 includes a substrate loading module 453 having robots 422A and a substrate unloading module 455 having robots 422B that are used to transfer substrates S to and from the receiving areas 424 into a desired position on the substrate carrier 411. The substrate transfer interface 440 may also include a robot 413 that is adapted to transfer the carrier 411 to one of the load lock chambers 402. In one embodiment, the robots 422A-422B are SCARA, six-axis, parallel, or linear type robots that can be adapted to transfer substrates from one position within the cluster tool 401 to another. Examples of a cluster tool and attached substrate transfer interface that may be adapted for use with one or more of the embodiments described herein is further disclosed in the commonly owned U.S. application Ser. No. 12/575,088 filed on Oct. 7, 2009, which is incorporated by reference in its entirety herein to the extent not inconsistent with the present disclosure.

In one embodiment, the processing chambers 403-408 are selectively sealably coupled to a transferring region 420C of the transfer chamber 420 by use of a slit valve (not shown). Each slit valve is configured to selectively isolate the processing region in each of the processing chambers 403-408 from the transferring region 420C and is disposed adjacent to the interface between the processing chambers 403-408 and the transfer chamber 420. In one embodiment, the transfer chamber 420 is maintained at a vacuum condition to eliminate or minimize pressure differences between the transfer chamber 420 and the individual processing chambers 403-408, which are typically used to process the substrates under a vacuum condition. In an alternate embodiment, the transfer chamber 420 and the individual processing chambers 403-408 are used to process the substrates in a clean and inert atmospheric pressure environment. It should be noted that the number and orientation of processing chambers (e.g., reference numerals 403-408) shown in the attached figures is not intended to limit the scope of the invention, since these configurational details can be adjusted without deviating from the basic scope of the invention described herein. Other embodiments of the invention may include a configuration with fewer or more chambers depending on the specific processing to be performed on the substrates without deviating from the scope of the present invention.

Generally, the substrate processing system 400 includes a system controller 190 configured to control the automated aspects of the system. The system controller 190 facilitates the control and automation of the overall cluster tool 401 and furnace 450 and may include a central processing unit (CPU) (not shown), memory (not shown), and support circuits (or I/O) (not shown). The CPU may be one of any form of computer processors that are used in industrial settings for controlling various chamber processes and hardware (e.g., conveyors, motors, fluid delivery hardware, etc.) and monitor the system and chamber processes (e.g., substrate position, process time, detector signal, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the system controller 190 determines which tasks are performable on a substrate. Preferably, the program is software readable by the system controller 190, which includes code to generate and store at least substrate positional information, the sequence of movement of the various controlled components, and any combination thereof.

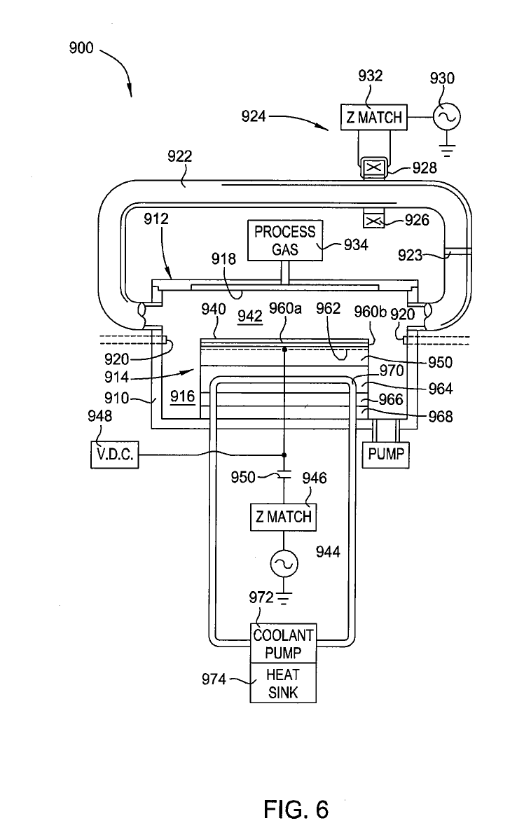

FIG. 4 is schematic plan view of one embodiment of a cluster tool 401 that includes six processing chambers 403-408, a load lock chamber 402, and a robot 413 disposed within the transferring region 420C of the transfer chamber 420. In one configuration, the processing chambers 405 and 406 are implant chambers, such as a P3i chamber (e.g., FIG. 6), and processing chambers 404-405 and 407-408 are thermal processing chambers, such as rapid thermal annealing (RTA) chambers. According to one embodiment of the invention, the cluster tool 401 includes a first process chamber 403 and a second process chamber 408 that are rapid thermal annealing (RTA) chambers, and a third process chamber 404 and a forth process chamber 407 that are implant chambers (e.g., P3i chambers).

In one embodiment, the furnace 450 disposed in the substrate processing system 400 comprises a belt type thermal anneal oven that is adapted to perform step 306. In one embodiment, the furnace 450 is a conveyor belt type furnace maintained at a temperature between about 800° C. and about 900° C. in the presence of nitrogen (N₂), oxygen (O₂), hydrogen (H₂), air, or combinations thereof. An example of a furnace design that may be adapted for use with one or more of the embodiments described herein is further disclosed in the commonly owned U.S. application Ser. No. 12/273,442, filed on Nov. 11, 2008 [Attorney Dkt No. APPM 13854.C1], which is incorporated by reference in its entirety herein to the extent not inconsistent with the present disclosure.

FIG. 5 illustrate various embodiments of the substrate processing system 500 that contains a cluster tool 401 and a furnace 451 or 452 that are each used to perform one or more of the processing steps in the processing sequences 300A-300C. In one embodiment, system 500 includes a cluster tool 401 that has six processing chambers 403-408, a load lock chamber 402, and a robot 413 disposed within the transferring region 420C of the transfer chamber 420, wherein at least two of the six processing chambers are implant chambers, such as P3i processing chambers. In one configuration, the processing chambers 403-408 are implant chambers, such as a P3i chamber (e.g., FIG. 6). According to one embodiment of the invention, the cluster tool 401 includes a first process chamber 403 and a second process chamber 408, which are both implant chambers (e.g., P3i chambers).

In one embodiment of system 500, a furnace 451 is disposed in the substrate processing system 500 that comprises a belt type thermal anneal oven that is adapted to perform steps 304 and 306, sequentially. In another embodiment of system 500, a furnace 452 is disposed in the substrate processing system 500 that comprises a belt type thermal anneal oven that is adapted to perform step 306 and then step 304. To perform the sequential thermal processing steps in either furnace 451 or furnace 452, the device may be segmented to contain different types of lamps, IR emitting devices or other similar thermal emitting components that can perform different thermal processes on a substrate as it passes through the furnace on a conveyor type device (e.g., left to right in FIG. 5). In some cases, the different segmented regions of a furnace 451, 452 may include different densities of lamps that are able to control and ramp the processing temperature in the substrate according to control signals sent from the controller 190. An example of a furnace design that may be adapted for use with one or more of the embodiments described herein is further disclosed in the commonly owned U.S. application Ser. No. 12/273,442, filed on Nov. 11, 2008 [Attorney Dkt No. APPM 13854.C1], which is incorporated by reference in its entirety herein to the extent not inconsistent with the present disclosure.

### Plasma Processing Chamber

Manufacturing high efficiency solar cells at low cost is key to making solar cells more competitive in the electrical generation industry. In an effort to inexpensively implant one or more doping materials within a solar cell substrate a plasma doping chamber may be used. A plasma doping chamber, such as the plasma ion immersion (P3i) chamber available from Applied Materials, Inc., is generally less expensive, has a smaller system foot print, is much less complex, and has a lower cost of ownership than conventional ion implantation devices. Unlike most beam-line ion implanters, the substrates sit on an electrical biased horizontal chuck, so many substrates can be implanted in a few seconds. Plasma ion immersion implantation also has the ability to achieve higher dopant dosing levels in a short time versus conventional furnace type diffusion type doping processes.

FIG. 6 illustrates an example of a plasma ion immersion implantation system. In FIG. 6, the plasma reactor has a cylindrical side wall 910, a ceiling 912 and a substrate contact-cooling electrostatic chuck 914. A pumping annulus 916 is defined between the chuck 914 and the sidewall 910. The reactor in the example of FIG. 6 is of the type in which process gases can be introduced through a gas distribution plate 918 (or “showerhead”) forming a large portion of the ceiling 912. While the substrate contact-cooling electrostatic chuck 914 may be employed in conjunction with any plasma source (such as an inductively coupled RF plasma source, a capacitively coupled RF plasma source or a microwave plasma source), the reactor in the example of FIG. 6 has a reentrant RF torroidal plasma source consisting of an external reentrant tube 922 coupled to the interior of the reactor through opposite sides of the sidewall 910. In one embodiment, the plasma reactor contains a plurality of torroidal sources (not shown) that are generally symmetrically arranged around the plasma reactor to improve the plasma density, plasma uniformity, and/or plasma process control. An insulating ring 923 provides a D.C. break along the reentrant tube 922. The torroidal plasma source further includes an RF power applicator 924 that may include a magnetically permeable torroidal core 926 surrounding an annular portion of the reentrant tube 922, a conductive coil 928 wound around a portion of the core 926 and an RF plasma source power generator 930 coupled to the conductive coil through an optional impedance match circuit 932. A process gas supply 934 is coupled to the gas distribution plate 918 to deliver a dopant containing gas. A solar cell substrate or workpiece 940 is placed on top of the chuck 914. A processing region 942 is defined between the substrate 940 and the ceiling 912 (including the gas distribution plate 918). A torroidal plasma current oscillates at the frequency of the RF plasma source power generator 930 along a closed torroidal path extending through the reentrant tube 922 and the processing region 942. RF bias power is applied to the chuck 914 by an RF bias power generator 944 through an impedance match circuit 946. A DC chucking voltage is applied to the chuck 914 from a chucking voltage source 948 isolated from the RF bias power generator 944 by an isolation capacitor 950.

Referring to FIG. 6, the chuck 914 has a top layer 950, referred to as a puck, consisting of insulative or semi-insulative material, such as aluminum nitride or aluminum oxide, which may be doped with other materials to control its electrical and thermal properties. A metal (molybdenum, for example) wire mesh or metal layer 962 inside of the puck 950 forms a cathode (or electrode) to which the chucking voltage is applied. The puck 950 may be formed as a ceramic. It is supported on a metal layer 964, preferably consisting of a metal having a high thermal conductivity, such as aluminum. The metal layer 964 rests on a highly insulative layer 966 whose thickness, dielectric constant and dielectric loss tangent are chosen to provide the chuck 914 with selected RF characteristics (e.g., capacitance, loss resistance) compatible with the reactor design and process requirements. A metal base layer 968 is connected to ground. The substrate 940 is held on the chuck 914 by applying a D.C. voltage from the chucking voltage source 948 to the electrode 962. One example of a material suitable for the puck semi-insulator or charge mobile layer is aluminum nitride. Another example is aluminum oxide, which may optionally be doped to increase charge mobility. For example, the dopant material may be titanium dioxide. RF bias power from the RF bias power generator 944 may be applied to the electrode 962 or, alternatively, to the metal layer 964 for RF coupling through the semi-insulative puck layer 950. In order to ensure a large heat transfer coefficient sufficient to maintain substrate temperature at high RF bias power levels (e.g., 5-10 kWatts), a large chucking voltage must be applied to the chuck 914, in the range of 1-4 kVolts.

In one example, a plasma ion immersion implantation process that may be used to implant boron, phosphorous, or arsenic can include introducing a precursor gas comprising a hydride or a fluoride of a dopant species, striking a plasma using a plasma source power in a two torroidal source conduits configuration between about 50 W and about 2 KW (preferably 500 W) at an RF voltage of 0.3 kV-10 kVpp (preferably 5 kVpp), setting a chamber pressure between about 5 and about 100 mtorr (preferably 20 mtorr), heating a solar cell substrate to a temperature between about 100° C. and about 1000° C. (preferably 600° C.), applying a bias power to the solar cell substrate on the order of 10 W-10 KW to drive the ionized dopant species towards the surface of the solar cell substrate. Examples of plasma ion immersion chamber and process that may be used to perform a plasma doping process are further disclosed in the commonly assigned U.S. Pat. No. 7,320,734, filed 8-22-2003, U.S. Pat. No. 7,288,491, filed 1-28-2005, and U.S. patent application Ser. No. 11/046,660, filed 1-28-2005, which are all incorporated by reference.

While the foregoing is directed to embodiments of the invention, other and further embodiments of the invention may be devised without departing from the basic scope thereof, and the scope thereof is determined by the claims that follow.

What is claimed is:

1. A method of forming a solar cell device, comprising:
disposing a first amount of a first dopant within a region of a substrate;
heating the substrate to a first temperature for a first period of time so that the first dopant diffuses a first depth within the substrate; and
heating the substrate to a second temperature for a second period of time so that the first dopant diffuses a second depth within the substrate.

2. The method of claim 1, further comprising depositing a metal layer over the region after heating the substrate to a first temperature and prior to heating the substrate to a second temperature, wherein heating the substrate to a second temperature is configured to cause the metal layer to densify.

3. The method of claim 2, wherein the metal layer comprises a metal selected from the group consisting of silver (Ag) and tin (Sn)

4. The method of claim 1, wherein the concentration of the first dopant in the region is greater than about 1×10²¹ atoms/cm³.

5. The method of claim 1, wherein first temperature is greater than the second temperature and the first period of time is less than the second period of time.

6. The method of claim 5, wherein first temperature is greater than about 950° C., the second temperature is less than about 950° C., the first period of time is less than 300 seconds and the second period of time is greater than 300 seconds.

7. The method of claim 1, wherein disposing the first amount of the first dopant within the region of the substrate comprises:
providing a gas containing a dopant material into a processing region of a plasma processing chamber;
generating a plasma in the processing region; and
biasing a substrate support to cause ions generated in the plasma to be disposed in the surface of the substrate.

8. The method of claim 1, wherein second temperature is greater than the first temperature, and the first period of time is greater than the second period of time.

9. The method of claim 1, wherein disposing a first amount of a first dopant within a region of a substrate comprises:
depositing a doped layer on a surface of substrate; and
heating the deposited doped layer to a temperature between about 1000° C. and about 1150° C.

10. A method of forming a solar cell device, comprising:
disposing a first amount of a first dopant within a region of a substrate;
heating the substrate to a first temperature for a first period of time so that the first dopant diffuses a first depth within the substrate; and
heating the substrate to a second temperature for a second period of time so that the first dopant diffuses a second depth within the substrate, wherein the second temperature is greater than the first temperature.

11. The method of claim 9, wherein the concentration of the first dopant in the region is greater than about 1×10²¹ atoms/cm³.

12. The method of claim 9, wherein the first period of time is greater than the second period of time.

13. The method of claim 9, wherein second temperature is greater than about 950° C., the first temperature is less than about 950° C., the first period of time is greater than 300 seconds and the second period of time is less than 300 seconds.

14. A processing system configured to form a portion of a solar cell device, comprising:
a cluster tool comprising:
a transfer chamber having a first transfer robot disposed therein;
two or more implant chambers coupled to the transfer chamber, wherein the two or more implant chambers each comprise:
a plasma source coupled to a processing region and adapted to maintain a generated plasma therein;
a gas distribution plate configured to distribute a gas to the processing region;
a substrate support having a biasing electrode and a substrate supporting surface, wherein the substrate supporting surface is configured to support a substrate in the processing region; and
an RF bias power generator coupled to the biasing electrode;
two or more second process chambers coupled to the transfer chamber and having a heat source configured to heat one or more substrates to a temperature greater than about 950° C.;
a load lock chamber coupled to the transfer chamber and having a substrate supporting surface configured to receive a substrate from the first transfer robot; and
a substrate interface module having a second transfer robot configured to transfer a substrate between the substrate interface module and the one or more regions of the load lock chamber; and
a furnace having a heat source configured to heat one or more substrates to a temperature between about 700 and about 950° C.

15. The processing system of claim 14, wherein the first transfer robot is configured to transfer an array of substrates.
